(19) United States
(12) Patent Application Publication
(10) Pub. No.: US 2009/0184422 A1
(43) Pub. Date: Jul. 23, 2009

(54) METHOD FOR FORMING METAL LINE OF SEMICONDUCTOR DEVICE WITHOUT PRODUCTION OF SIDEWALL OXIDE IN METAL LINE FORMING REGION

(76) Inventors: Ga Young HA, Gyeonggi-do (KR); Chang Jun YOO, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/329,665

(22) Filed: Dec. 8, 2008

(30) Foreign Application Priority Data
Jan. 18, 2008 (KR) 10-2008-0005900

(51) Int. Cl. H01L 21/768; H01L 23/532

(52) U.S. Cl. 257/751; 438/643; 257/E21.584; 257/E23.157

(57) ABSTRACT

A method for forming a metal line of a semiconductor device includes forming an insulation layer having a contact hole over a semiconductor substrate. Any one of a TiN layer and a TaN layer is formed on the insulation layer, including a surface of the contact hole, and an anti-reflection layer is formed on any one of the TiN layer and the TaN layer. A trench is defined at an upper end of the contact hole by etching the anti-reflection layer, any one of the TiN layer and the TaN layer, and the insulation layer. Subsequently, the anti-reflection layer is removed and a metal layer is formed to fill the trench and the contact hole.

### CROSS-REFERENCE TO RELATED APPLICATIONS

The present application claims priority to Korean patent application number 10-2008-0005900 filed on Jan. 18, 2008, which is incorporated herein by reference in its entirety.

### BACKGROUND OF THE INVENTION

The present invention relates generally to a method for forming a metal line of a semiconductor device, and more particularly, to a method for forming a metal line of a semiconductor device which can improve a damascene process.

In a semiconductor device, metal lines are formed to electrically connect elements or lines with each other. Contact plugs are formed to connect lower metal lines and upper metal lines with each other.

The metal line of a semiconductor device is usually formed of a material such as aluminum or tungsten because such materials have good electrical conductivity. Copper is being studied as a potential next-generation material for a metal line because copper has excellent electrical conductivity and low resistance when compared to aluminum and tungsten. Forming the metal line of a semiconductor device with Copper (Cu) can therefore solve the problems associated with conventional metal lines of highly integrated semiconductor devices having high operating speed such as RC signal delay. It is difficult to dry-etch copper into a wiring pattern, and therefore to form a metal line using copper a damascene process is employed.

In the damascene metal line forming process, a metal line forming region is defined by etching an insulation layer formed on a semiconductor substrate, and, after depositing a copper layer to fill the metal line forming region, by chemically mechanically polishing (CMPing) the copper layer, a metal line is formed. The damascene process can be a single damascene process or a dual damascene process.

Hereafter, a method for manufacturing a semiconductor device, including a process for forming a metal line according to the conventional art, will be briefly described.

An insulation layer is formed on a semiconductor substrate, and then a contact hole is defined in the insulation layer by etching the insulation layer. An anti-reflection layer is formed on the insulation layer including the contact hole, and then a photoresist pattern is formed on the anti-reflection layer. A trench is formed over the contact hole, by etching the anti-reflection layer and the insulation layer using the photoresist pattern as an etch mask, and by this etching a metal line forming region having the contact hole and the trench is defined. A diffusion barrier is formed on the insulation layer including the metal line forming region, and then a metal layer, e.g., a copper layer, for a metal line is deposited on the diffusion barrier to fill the metal line forming region. Then, a metal line is formed by CMPing the copper layer to expose the insulation layer.

However, in the conventional art as described above, after the trench is defined, a portion of the anti-reflection layer remains in the contact hole due to the narrow width of the contact hole, and as a result, a byproduct, such as an oxide, is produced during an etching process adheres to the sidewall of the remaining anti-reflection layer. This aspect of the conventional art is problematic in that the deposition of the metal layer in a subsequent process cannot be appropriately implemented because of the oxide that adheres to the sidewall of the remaining anti-reflection layer.

That is, according to the conventional method, when conducting an etching process for the insulation layer to define the trench, SF₆ gas and CFCl₃ gas are used as etchant gases. These etchant gases perform an etching task by converting the insulation layer made of an SiO₂ layer into volatile SiClₓH_{y}. At this time, as the insulation layer is etched, Cl and H, which are easily oxidized, are volatilized, and a byproduct such as an oxide (SiO₂) is produced. The byproduct adheres to the sidewall of the anti-reflection layer. Also, the byproduct remains even after the anti-reflection layer is removed and serves as a factor that disrupts the deposition of the metal layer in a subsequent process.

### SUMMARY OF THE INVENTION

Embodiments of the present invention include a method for forming a metal line of a semiconductor device which can improve a damascene process.

In one aspect of the present invention, a method for forming a metal line of a semiconductor device comprises the steps of forming an insulation layer having a contact hole over a semiconductor substrate; forming any one of a TiN layer and a TaN layer on the insulation layer including a surface of the contact hole; forming an anti-reflection layer on any one of the TiN layer and the TaN; defining a trench at an upper end of the contact hole by etching the anti-reflection layer, any one of the TiN layer and the TaN layer, and the insulation layer; removing the anti-reflection layer; and forming a metal layer to fill the trench and the contact hole.

The TiN layer or the TaN layer is formed through PVD or CVD.

The TiN layer or the TaN layer is formed to have a thickness of 20˜100 Å.

The step of defining the trench is implemented in a manner such that the TiN layer or the TaN layer and the insulation layer have the same etching selectivity or etching selectivity of the TiN layer or the TaN layer is greater than etching selectivity of the insulation layer.

Etching of the TiN layer or the TaN layer and the insulation layer with the same etching selectivity is conducted by flowing etchant gas of the TiN layer or the TaN layer and etchant gas of the insulation layer at a flow ratio of 1:0.8˜1:1.2.

The etchant gas of the TiN layer or the TaN layer includes Cl₂ gas, and the etchant gas of the insulation layer includes SF₆ gas.

The etching of the TiN layer or the TaN layer and the insulation layer with the same etching selectivity is conducted by flowing the etchant gas of the TiN layer or the TaN layer, the etchant gas of the insulation layer, and Ar gas.

The etching of the TiN layer or the TaN layer and the insulation layer with the same etching selectivity is conducted with RF power of 150˜200 W and DC power of 5˜15 W.

After the step of removing the anti-reflection layer and before the step of forming the metal layer, the method further comprises the step of forming a diffusion barrier on the insulation layer including surfaces of the trench and the contact hole.

The metal layer comprises a copper layer.

In another aspect of present invention, a metal line of a semiconductor device, comprised an insulation layer formed over a semiconductor substrate and having a contact hole and a trench at an upper end of the contact hole; any one of a TiN layer and a TaN layer formed on the upper surface of insulation layer and a surface of the contact hole; a diffusion barrier formed on any one of a TiN layer and a TaN layer on the upper surface of the insulation layer and the surface of the contact hole and the surface of the trench; and a metal layer formed the diffusion barrier to fill the trench and the contact hole.

The TiN layer or the TaN layer has a thickness in the range of 20 to 100 Å.

The metal layer comprises a copper layer.

### BRIEF DESCRIPTION OF THE DRAWINGS

FIGS. 1A through 1H are cross-sectional views showing the processes of a method for forming a metal line of a semiconductor device in accordance with an embodiment of the present invention.

### DESCRIPTION OF SPECIFIC EMBODIMENT

Hereafter, the specific embodiment of the present invention will be described in detail with reference to the attached drawings.

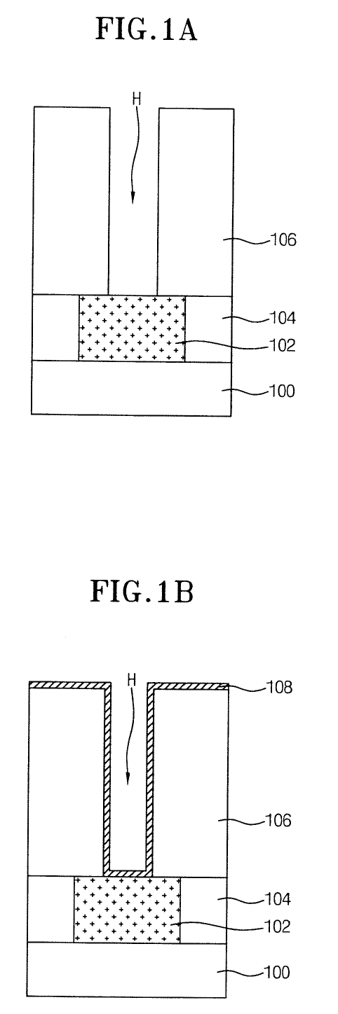

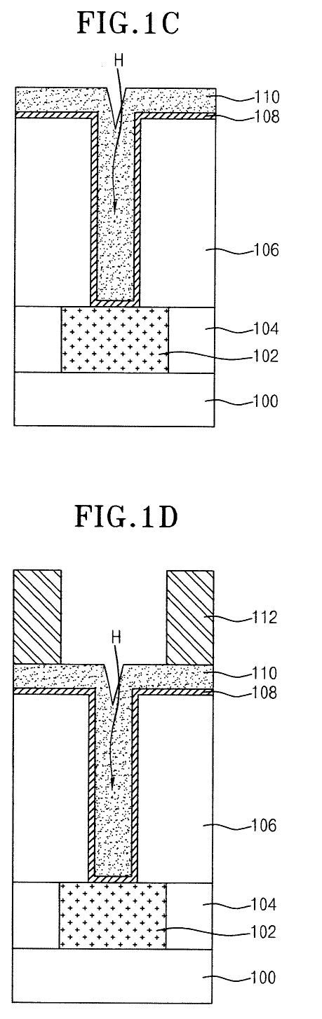

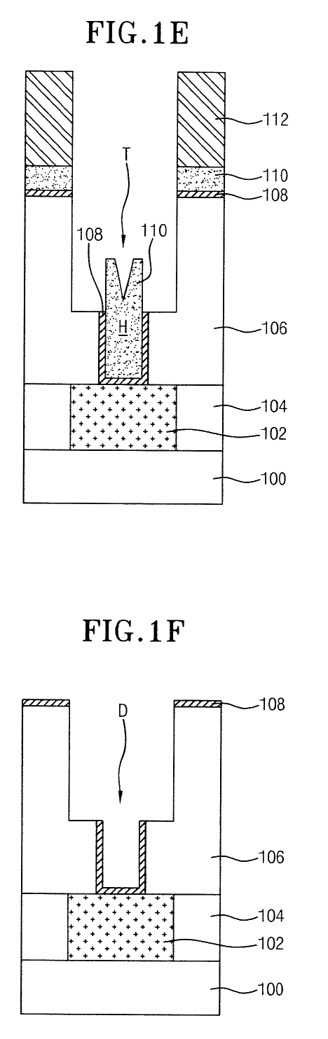

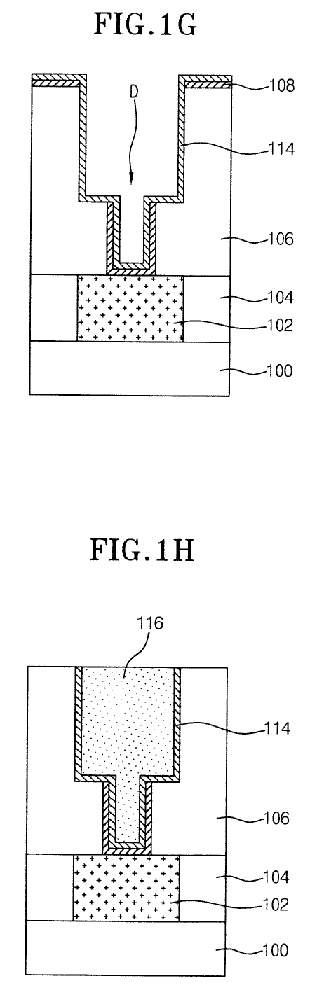

FIGS. 1A through 1H are cross-sectional views showing the processes of a method for forming a metal line of a semiconductor device in accordance with an embodiment of the present invention.

Referring to FIG. 1A, a lower metal line 102 is formed by depositing a metal layer, for example, an aluminum layer, on a semiconductor substrate 100 and then etching the aluminum layer. The semiconductor substrate is formed with a predetermined understructure (not shown). A first insulation layer 104 is formed to cover the lower metal line 102, a second insulation layer 106 is formed on the first insulation layer 104. Subsequently, a contact hole H is defined in the second insulation layer 106 by etching the second insulation layer 106 such that the hole H defined in the second insulation layer 106 exposes the lower metal line 102.

Referring to FIG. 1B, a TiN layer 108 is formed on the second insulation layer 106 including the surface of the contact hole H. The TiN layer 108 is formed, for example, through physical vapor deposition (PVD) or chemical vapor deposition (CVD), preferably, to have a thickness of 20˜100 Å.

Referring to FIG. 1C, an anti-reflection layer 110 is formed on the TiN layer 108. The anti-reflection layer 110 may be formed to partially or completely fill the contact hole H.

Referring to FIG. 1D, a photoresist pattern 112 is formed on the anti-reflection layer 110 to expose the contact hole H. Preferably, the photoresist pattern 112 is formed to expose both the contact hole H and a portion of the anti-reflection layer 110 around the contact hole H such that a trench having a greater width than the contact hole H can be defined at the upper end of the contact hole H.

Referring to FIG. 1E, a trench T is defined at the upper end of the contact hole H by etching the anti-reflection layer 110, the TiN layer 108, and the second insulation layer 106 which are exposed through the photoresist pattern 112. According to the present embodiment, the trench T is defined to have a width greater than the contact hole H.

An etching process for defining the trench T is conducted in a manner such that the TiN layer 108 and the second insulation layer 106, made of an oxide layer, have the same etching selectivity. The etching of the TiN layer 108 and the second insulation layer 106 with the same etching selectivity is conducted by flowing Cl₂ gas as the etchant gas of the TiN layer 108 and SF₆ gas as the etchant gas of the second insulation layer 106 at a flow ratio of 1:0.8˜1:1.2, and preferably at a flow rate of 1:1. At this time, it is preferred that Ar gas be flowed together with the Cl₂ gas and the SF₆ gas. Also, the etching of the TiN layer 108 and the second insulation layer 106 with the same etching selectivity is conducted with radio frequency (RF) power of 150˜200 W and direct current (DC) power of 5˜15 W. By etching the TiN layer 108 and the second insulation layer 106 in this way, the TiN layer 108 and the second insulation layer 106 made of an oxide layer can be etched together to define the trench T.

When conducting the etching process to define the trench T, it is conceivable that the etch rate of the TiN layer 108 can be decreased such that the TiN layer 108 may serve as an etch stop layer for the second insulation layer 106.

In the present invention, since the etching process for defining the trench T is conducted such that the TiN layer 108 and the second insulation layer 106 made of an oxide layer are etched together, the byproduct, such as an oxide, produced by the etchant gases is removed. Accordingly, in the present invention, the byproduct that is problematic in the conventional art, such as an oxide, does not adhere to the portion of the sidewall of the anti-reflection layer 110 that remains in the contact hole H.

Referring to FIG. 1F, the photoresist pattern 112 and the anti-reflection layer 110 are removed. As a consequence, an upper metal line forming region D, which includes the trench T and the contact hole H, is defined on the semiconductor substrate 100 to expose the lower metal line 102.

Referring to FIG. 1G, a diffusion barrier 114 is formed on the TiN layer 108 including the surface of the upper metal line forming region D. According to the present embodiment, the diffusion barrier 114 is formed as a metal-based layer. Here, in the present invention, because the TiN layer 108 is formed prior to the forming of the diffusion barrier 114, the diffusion barrier 114 can be formed more easily than in the conventional art.

Referring to FIG. 1H, a metal layer for a metal line is formed on the diffusion barrier 114 to fill the upper metal line forming region D. The metal layer for a metal line preferably comprises a copper layer (not shown). Next, an upper metal line 116 which contacts the lower metal line 102 is formed by removing the copper layer, the diffusion barrier 114, and the TiN layer 108 until the second insulation layer 106 is exposed.

As is apparent from the above description, in the present invention, since a trench is defined by simultaneously etching a TiN layer and a second insulation layer in the state in which the TiN layer is formed on the second insulation layer including the surface of a contact hole, the byproduct, such as an oxide, produced while conducting an etching process to define the trench can be removed. Thus, in the present invention, it is possible to prevent the byproduct that is problematic in the conventional art, such as an oxide, from adhering to the sidewall of an anti-reflection layer, and through this, the deposition of a metal layer in a subsequent process can be appropriately implemented. As a result, in the present invention, a damascene process for forming a metal line can be greatly improved.

In the above embodiment of the present invention, by forming the TiN layer on the second insulation layer including the surface of the contact hole, the TiN layer and the second insulation layer can be simultaneously etched. However, in another exemplary embodiment of the present invention, by forming a TaN layer instead of the TiN layer, the same effects as those of the aforementioned embodiment can be obtained.

In this case, it is to be understood that the other configuration, with the exception of the formation of the TaN layer instead of the TiN layer, is the same as that of the aforementioned embodiment.

Although a specific embodiment of the present invention has been described for illustrative purposes, those skilled in the art will appreciate that various modifications, additions, and substitutions are possible, without departing from the scope and the spirit of the invention as disclosed in the accompanying claims.

What is claimed is:

1. A method for forming a metal line of a semiconductor device, comprising the steps of:
forming an insulation layer having a contact hole over a semiconductor substrate;
forming any one of a TiN layer and a TaN layer on the insulation layer and a surface of the contact hole;
forming an anti-reflection layer on any one of the TiN layer and the TaN layer;
defining a trench at an upper end of the contact hole by etching predetermined portions of the anti-reflection layer, the TiN layer, and the insulation layer;
removing the anti-reflection layer; and
forming a metal layer to fill the trench and the contact hole.

2. The method according to claim 1, wherein the TiN layer or the TaN layer is formed through physical vapor deposition (PVD) or chemical vapor deposition (CVD).

3. The method according to claim 1, wherein the TiN layer or the TaN layer is formed to have a thickness in the range of 20 to 100 Å.

4. The method according to claim 1, wherein in the step of defining the trench an etching selectivity of the TiN layer or the TaN layer is greater than or equal to an etching selectivity of the insulation layer.

5. The method according to claim 4, wherein the etching selectivity of the TiN layer or the TaN layer is equal to the etching selectivity of the insulation layer and an etching of the TiN layer or lo the TaN layer and the insulation layer is conducted by flowing an etchant gas of the TiN layer or the TaN layer and an etchant gas of the insulation layer at a flow ratio in the range of 1:0.8 to 1:1.2.

6. The method according to claim 5, wherein the etchant gas of the TiN layer or the TaN layer comprises Cl₂ gas, and the etchant gas of the insulation layer comprises SF₆ gas.

7. The method according to claim 5, wherein the etching of the TiN layer or the TaN layer and the insulation layer is conducted by flowing the etchant gas of the TiN layer or the TaN layer, the etchant gas of the insulation layer, and Ar gas.

8. The method according to claim 4, wherein the etching selectivity of the TiN layer or the TaN layer is equal to the etching selectivity of the insulation layer and an etching of the TiN layer or the TaN layer and the insulation layer is conducted with a radio frequency (RF) power in the range of 150 to 200 W and a direct current (DC) power in the range of 5 to 15 W.

9. The method according to claim 1, wherein, after the step of removing the anti-reflection layer and before the step of forming the metal layer, the method further comprises the step of:
forming a diffusion barrier on the insulation layer and surfaces of the trench and the contact hole.

10. The method according to claim 1, wherein the metal layer comprises a copper layer.

11. A metal line of a semiconductor device, comprising:
an insulation layer formed over a semiconductor substrate and having a contact hole and a trench at an upper end of the contact hole;
any one of a TiN layer and a TaN layer formed on the upper surface of insulation layer and a surface of the contact hole;
a diffusion barrier formed on any one of a TiN layer and a TaN layer on the upper surface of the insulation layer and the surface of the contact hole and the surface of the trench; and
a metal layer formed the diffusion barrier to fill the trench and the contact hole.

12. The metal line according to claim 11, wherein the TiN layer or the TaN layer has a thickness in the range of 20 to 100 Å.

13. The metal line according to claim 11, wherein the metal layer comprises a copper layer.
